(19) United States
(12) Patent Application Publication
(10) Pub. No.: US 2024/0007827 A1
(43) Pub. Date: Jan. 4, 2024

(54) METHOD AND APPARATUS FOR RESOURCE-EFFICIENT INDOOR LOCALIZATION BASED ON CHANNEL MEASUREMENTS

(71) Applicant: HUAWEI TECHNOLOGIES CO., LTD., Shenzhen (CN)

(72) Inventors: George Arvanitakis, Munich (DE); Nikolaos Liakopoulos, Boulogne Billancourt (FR); Dimitrios TSILIMANTOS, Boulogne Billancourt (FR); Jean-Claude Belfiore, Boulogne Billancourt (FR); Yanchun Li, Wuhan (CN)

(21) Appl. No.: 18/339,751

(22) Filed: Jun. 22, 2023

Related U.S. Application Data
(63) Continuation of application No. PCT/EP2020/087721, filed on Dec. 22, 2020.

(51) Int. Cl. H04W 4/029; H04W 16/22

(52) U.S. Cl. CPC H04W 4/029; H04W 16/225

(57) ABSTRACT

An apparatus and method are provided for estimating a refined location in dependence on a plurality of measurements of one or more communication channels. The apparatus comprises one or more processors configured to: compress each channel measurement; process the compressed channel measurements using a neural network to form a plurality of intermediate location estimates; and process the intermediate location estimates to form the refined location.

### CROSS-REFERENCE TO RELATED APPLICATIONS

This application is a continuation of International Application No. PCT/EP2020/087721, filed on Dec. 22, 2020, the disclosure of which is hereby incorporated by reference in its entirety.

### TECHNICAL FIELD

Embodiments of the present disclosure relate to indoor localization. More particularly, embodiments of the present disclosure relate to a method and an apparatus for estimating a refined location.

### BACKGROUND

Indoor localization has become a key requirement for a fast-growing range of applications. Many industries, including commercial, inventory tracking and military, have recently shown great interest in this technology.

An indoor localization system can be used to determine the location of people or objects in indoor scenarios where satellite technologies, such as GPS, are not available or lack the desired accuracy due to the increased signal propagation losses caused by the construction materials. Typical use cases are inside buildings, airports, warehouses, parking garages, underground locations, mines and Internet-of-Things (IoT) smart environments.

A variety of proposed techniques exist based on the available equipment, such as digital cameras, inertial measurement units (IMUs), WiFi or Bluetooth antennas, and infrared, ultrasound or magnetic field sensors. From these alternatives, indoor localization based on wireless technologies has attracted significant interest, mainly due to the advantage of reusing an existing wireless infrastructure that is widely used, such as WiFi, leading to low deployment and maintenance costs.

There are several types of measurements of the wireless signal that can be used for this purpose, such as the Received Signal Strength (RSS), Channel State Information (CSI), Time of Arrival (ToA), Time of Flight (ToF), Angle of Arrival (AoA) and Angle of Departure (AoD). Whilst classical approaches, such as triangulation or trilateration, that try to estimate the location by using geometric properties and tools can be used, a commonly used setup currently utilizes fingerprinting based on channel measurements such as RSS, or the more fine-grained CSI that has lower hardware requirements. This approach becomes even more attractive with the recent rise and success of Deep Neural Networks (DNNs), which can greatly enhance the performance of fingerprinting.

In indoor localization with fingerprinting, first, channel measurements from known locations are collected and stored. Then, these measurements are processed in order to identify and extract features that can be used to generate a fingerprint database, where each fingerprint uniquely identifies the original known location. If DNNs are used, in the training phase the DNN is trained to keep only the information of the input signal that is relevant to the position. The main benefit of using fingerprints is to avoid the comparison and transmission of bulky data. During the online prediction phase, each time a new signal is received from an unknown location, the database is used to find the best matching fingerprint and its associated location. With DNNs, this is performed in the inference phase where the location of the received signal is estimated by a feed-forward pass through the trained DNN.

In addition to the low infrastructure cost, indoor localization based on channel measurements may provide high accuracy, which can be further increased by applying post-processing techniques.

However, due to the large quantity of measurements that need to be stored and processed, such methods also have high power, computational and memory requirements. At the same time, as DNN models become more efficient and robust, they also become highly complex, which greatly increases the energy and required computational and memory resources to be effectively trained and used for inference. As a result, although indoor localization is widely recognized as a high value problem, recent research has not achieved a single widely accepted solution that has the desired accuracy at the required cost.

Prior methods have shown that using DNNs for fingerprinting may provide high accuracy for indoor localization. DNNs can be applied with CSI or RSS channel measurements in WiFi. However, such previous methods do not offer a resource efficient solution. DNN-based localization generally requires expensive measurement campaigns and the cost in storage and processing does not grow only with the frequency of sample measurements, but also with the location area size. The lack of low power systems and methods for processing the channel measurements and training the DNN, even on the device, is therefore a major limitation of the prior art.

It is desirable to develop an apparatus and method for indoor localization that overcomes such problems.

### SUMMARY

According to one aspect, there is provided an apparatus for estimating a refined location in dependence on a plurality of measurements of one or more communication channels, the apparatus comprising one or more processors configured to: compress each channel measurement; process the compressed channel measurements using a neural network to form a plurality of intermediate location estimates; and process the intermediate location estimates to form the refined location.

The apparatus may allow for a resource-efficient approach that may greatly reduce the memory required to store data at a device and allow performance of the training and inference steps in low-power or resource-constrained devices.

Each channel measurement may be compressed to a binary form. The neural network may be a binary neural network configured to operate in accordance with a neural network model defined by a set of weights. All the weights may be binary digits. The channel measurements may advantageously be compressed into a minimum size binary representation which contains sufficient information for performing effective training and inference. The one or more processors may be configured to implement the neural network model using bitwise operations. Preferably, only bitwise operations are used. This may improve the computational efficiency.

The one or more processors may be configured to: process the binary forms of the channel measurements using the neural network to form a respective measure of confidence for each intermediate location estimate; and estimate the refined location in dependence on the measures of confidence. This may further improve the quality of the location estimate.

Each channel measurement may be indicative of an estimate of channel state information (CSI) for one or more radio frequency channels and on one or more antennas. This may enable indoor localization without dedicated hardware and may enable having the receiver and localization processes on the device, due to the great reduction in the computation, memory and power requirements.

The one or more processors may be configured to digitally pre-process each channel measurement. The pre-processing may include Digital Signal Processing methods, such as phase sanitization and amplitude normalization. The pre-processing step may take into account specific properties of the localization problem. This may allow more accurate and robust location determination.

The one or more processors may be configured to delete each channel measurement once it has been compressed. This may reduce memory and computation requirements.

Each channel measurement (CSI measurement) may be represented by a complex value comprising a real part and an imaginary part. The one or more processors may be configured to process each channel measurement by selecting a refined representation which comprises the amplitude of the complex value and the real part. For CSI-based localization, this may take into consideration the effect of uncertainty in delay and initial phase between CSI measurements taken from the same location and may erase the noise of measurements by discarding these artifacts.

The one or more processors may be configured to compress the refined representation of the channel state information estimates for each channel measurement into a compressed representation. This may reduce memory and computation requirements.

The refined location may be an estimate of the location of the apparatus. This may allow the location of the apparatus to be determined on-device.

The neural network may be configured to operate as a multi-class classifier. A class estimate may correspond to a location on a discretized space. Such an approach may exhibit strong generalization and robust performance, with low complexity.

According to another aspect, there is provided a mobile device comprising one or more processors configured to: receive a set of channel measurements for radio frequency channels; compress each channel measurement to a compressed form; transmit the compressed forms of the channel measurements to a server; receive from the server a set of neural network weights; and implement a neural network using the received weights to estimate a location of the mobile device. This may allow one or more mobile devices to provide compressed (and optionally pre-processed) measurements quickly and with reduced communication overhead to a server that performs the training, and then the binary trained model can be easily disseminated to the devices.

The mobile device may comprise a radio receiver. The channel measurements may be formed by the radio receiver. This may allow the refined location to be determined at the mobile device.

According to another aspect, there is provided a computer-implemented method for estimating a refined location in dependence on a plurality of measurements of one or more communication channels, the method comprising: compressing each channel measurement; processing the compressed channel measurements using a neural network to form a plurality of intermediate location estimates; and processing the intermediate location estimates to form the refined location.

According to a further aspect, there is provided a computer-readable medium defining instructions for causing a computer to perform a method for estimating a refined location in dependence on a plurality of measurements of one or more communication channels, the method comprising: compressing each channel measurement; processing the compressed channel measurements using a neural network to form a plurality of intermediate location estimates; and processing the intermediate location estimates to form the refined location. The computer-readable medium may be a non-transitory computer-readable medium.

The method may allow for a resource efficient approach that may greatly reduce the memory required to store data at a device and allow performance of the training and inference steps in low power or resource-constrained devices.

### BRIEF DESCRIPTION OF THE DRAWINGS

Embodiments of the present disclosure will now be described by way of example with reference to the accompanying drawings.

In the drawings:

FIG. 1 illustrates the modules of the indoor localization system according to an embodiment of the present disclosure.

FIG. 2 schematically illustrates an offline binary compression module according to an embodiment of the present disclosure.

FIG. 3 schematically illustrates an online binary compression module according to an embodiment of the present disclosure.

FIG. 4 schematically illustrates an online binary compression module with thresholding according to an embodiment of the present disclosure.

FIG. 5 schematically illustrates a location estimator module with feedback from the binary network module according to an embodiment of the present disclosure.

FIG. 6 schematically illustrates an embodiment utilizing a centralized training protocol.

FIG. 7 schematically illustrates a method for estimating a refined location in dependence on a plurality of measurements of one or more communication channels according to an embodiment of the present disclosure.

FIG. 8 schematically illustrates an apparatus configured to perform a method according to an embodiment of the present disclosure.

FIG. 9 schematically illustrates a mobile device configured to communicate with a server according to an embodiment of the present disclosure.

FIG. 10 shows a comparison of the memory requirements for the neural network of the system according to an embodiment of the present disclosure and a DNN implementation.

FIG. 11 shows a comparison of the accuracy of the system according to an embodiment of the present disclosure and a DNN implementation.

### DETAILED DESCRIPTION

Embodiments of the present disclosure include an apparatus and a method for resource-efficient indoor localization based on communication channel measurements. Embodiments of the present disclosure advantageously adopt a much lighter arithmetic representation, while maintaining high inference accuracy. The described architecture can facilitate training, allowing the use of efficient training algorithms on the binary field, and benefits from low energy and resource consumption. The described approach may in some implementations greatly reduce the memory required to store data at a device and allow performance of the training and inference steps in low-power or resource-constrained devices.

In the approach described herein, the indoor localization is based on communication channel measurements, for example, radio frequency measurements formed by a radio receiver of a mobile device. The channel measurements may be indicative of an estimate of channel state information (CSI) for one or more radio frequency channels and on one or more antennas. CSI refers to known channel properties of a communication link. This information describes how a signal propagates from the transmitter to the receiver and may represent the combined effect of, for example, scattering, power decay and fading with distance.

In the preferred implementation, the main block exploits binary compression to feed a binary neural network, and then combines the results of binary classification and multi-sample post-processing to achieve high accuracy and strong generalization.

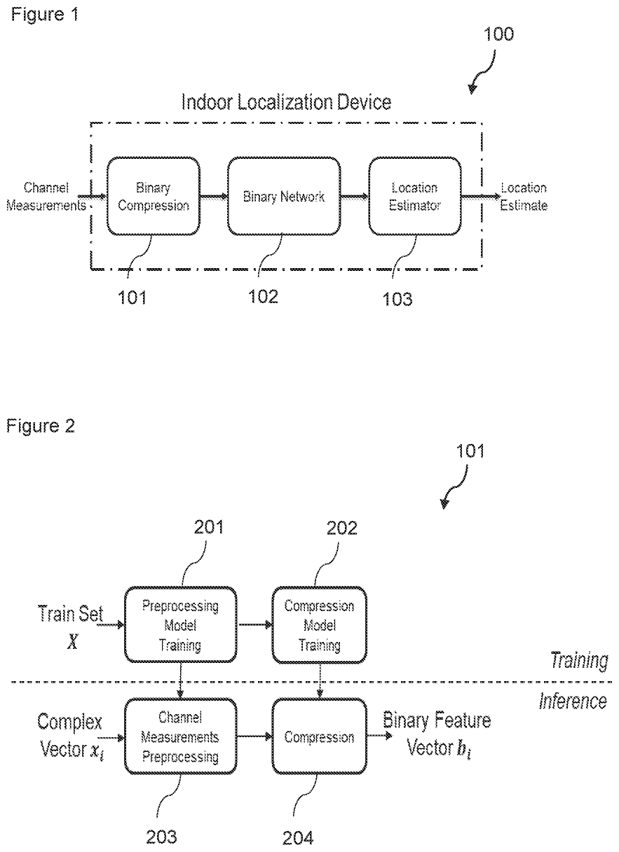

As schematically illustrated in the example of FIG. 1, the main block 100 comprises three modules: a binary compression module 101, a binary network module 102 and a location estimator 103. These modules are described in more detail below.

The purpose of the binary compression module 101 is twofold. Firstly, it is configured to pre-process the channel measurements (where desired) and secondly, it is configured to compress the channel measurements into a minimum size binary representation. The minimum size binary representation contains sufficient information to allow the binary network module 102 to perform effective training and inference.

The pre-processing step may include Digital Signal Processing (DSP) methods, such as phase sanitization and amplitude normalization. The pre-processing step may take into account specific properties of the localization problem. More precisely, for CSI-based localization, it may take into consideration the effect of uncertainty in delay and initial phase between CSI measurements taken from the same location and may erase the noise of measurements by discarding these artifacts, allowing more accurate and robust fingerprinting.

To achieve this behavior, a suitable representation for the high-precision complex value of the CSI can be selected, which is later used to extract key features. A complex number is written as z=a+bi=re^{iφ}, where a, b ∈ [symbol] is the real and imaginary part respectively, r=|z|=\sqrt{a²+b²} is the amplitude or absolute value, φ=arg(z) is the phase and i represents the imaginary unit. The phase of this complex number is generally not a good choice as it is sensitive to noise when the amplitude is small. On the other hand, the amplitude r is a better option, since it is invariant to delay and initial phase uncertainty. The difference between selecting the real part or the imaginary part is found to be small. In one embodiment of the present disclosure, the amplitude r and the real part a are selected as the representation of the complex CSI value z during the pre-processing phase.

The compression step includes receiving an input vector of n high precision features and outputting a vector of n′ binary features. Depending on the memory and computation capabilities of the localization device, this step may include methods such as binary agglomeration clustering, binary Primary Component Analysis (PCA), random projections, thresholding, restricted Boltzmann machine and auto-encoders.

FIG. 2 shows an offline implementation of the binary compression module 101. In the training mode, the input is a training dataset X. The pre-processing model is trained at 201 and the compression model is trained at 202. In the inference mode, the input is a complex vector xᵢ. The channel measurements are pre-processed at 203. The pre-processed channel measurements are compressed at 204. The output is a binary feature vector bᵢ.

In this approach, the full high-precision dataset X is initially stored, pre-processed and compressed to allow the training of the module parameters. Then, during inference, this trained model is used to provide a binary feature vector for each input complex vector. In one embodiment, the input x ∈ [symbol] ^{k} is in general a vector of k complex numbers for a single measurement, where k is the number of CSI values for different system dimensions, such as frequencies and antennas, that are required to describe one measurement and its actual value depends on the system configuration.

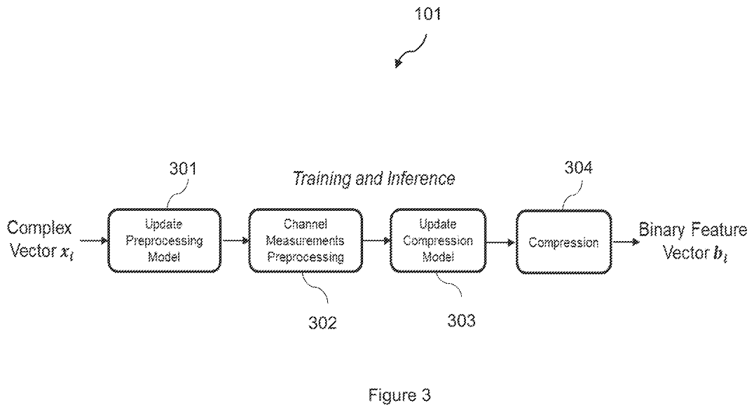

In an alternative implementation of the binary compression module 101, as shown in FIG. 3, the pre-processing and compression are performed in an online fashion for training and inference. The input is a complex vector xᵢ. The pre-processing model is updated at 301 and the channel measurements are pre-processed at 302. The compression model is updated at 303 and the channel measurements are compressed at 304. The output is a binary feature vector bᵢ.

This approach has the significant advantage that there is no need to store the full dataset X of high-precision raw CSI measurements, while data becomes available in a sequential order. Each new measurement is processed and used to update the trainable parameters of the binary compression module 101.

The purpose of the binary network module 102 is to train a neural network based on the binary features provided by the binary compression module 101 and to perform inference using the trained model in order to determine the location of the device at the location estimator 103. Using this approach, both the training and inference phases can be executed on the device, even on energy-constrained devices, unlike the common approach where the training is performed in the cloud, where the resource limitations are relaxed.

In order to have such a standalone training functionality, a Binary Neural Network (BNN) can first be used, which takes advantage of the extreme arithmetic representation of 1-bit for the learning parameters (neuron weights), inputs, outputs and activation functions, compared to the floating point precision of 32-bit or 64-bit that is commonly used in DNNs. The lower the bit representation, the higher the achieved compression can be. This can have a significant impact when millions of numbers need to be stored and processed for the input vectors and the neuron weights.

Training BNNs is challenging due to the nature of binary weights, since the standard back-propagation algorithm that is used for training continuous DNNs can no longer be directly applied, as it is based on computing gradients. It has been shown that the gradients become unstable as soon as the number of bits representing numbers is small, let alone to be a single binary value. Thus, the design and training methodology for the introduced BNN is chosen to allow high accuracy with good generalization properties. In one embodiment of the present disclosure, the architecture of the binary projection-coding block is adopted, where coding theory and optimization are combined to achieve learning and inference in the binary field. This provides a flexible design where the parameters, such as the number of neurons, layers and committee members, can be fine-tuned according to the memory and power capabilities of the device.

The indoor localization problem is formulated as a classification problem, a type of supervised learning, which together with the fact that a BNN is used, exhibits strong generalization and robust performance, with low complexity. For this purpose, the location area of interest is divided into smaller parts that may overlap or not, and each one is allocated a class identifier. Then, the output layer of the Binary Network predicts the class to which a CSI measurement belongs. The size of the output layer, i.e. the number of neurons in the output layer, is determined by the number of different classes. In one embodiment of the present disclosure, the area is divided into a grid, and the size of the output layer is therefore determined by the grid granularity.

The location estimator module 103 is configured to estimate the accurate location of the device based on processing a multitude of location estimates generated by the binary network module 102 during inference.

The accurate location estimate from the location estimator module 103 is preferably based on statistical analysis of subsequent location estimates produced by the inference phase of the binary network module 102. The location estimator module 103 selects a subset from a stream of location estimates incoming from the binary network module 102, i.e. it subsamples the output of the binary network module 102. Then, it can apply a single or multiple statistical analysis methods, such as clustering, averaging and discarding of outliers, in order to strengthen the final location estimation.

The location estimator module 103 may also receive feedback signals from the binary network module 102 that can help determine the quality and thus the importance of each output sample. This feedback can be used by the location estimator module 103 to allocate appropriate weights in each CSI measurement, so that the final weighted decision is biased towards the samples for which the binary network module 102 is more confident.

Further exemplary implementations of each module will now be described in more detail.

In one embodiment of the binary compression module 101, the channel measurement of complex CSI values may be represented as an input vector of length 2k of high precision features, where the factor 2 takes into account the real and the imaginary part of a complex CSI value and k is the product of different subcarriers (frequencies) and antennas that describe a single measurement. For example, in one setting, there may be a 1×4 SIMO channel with 30 subcarriers that leads to 4×30×2=240 high precision features per input vector.

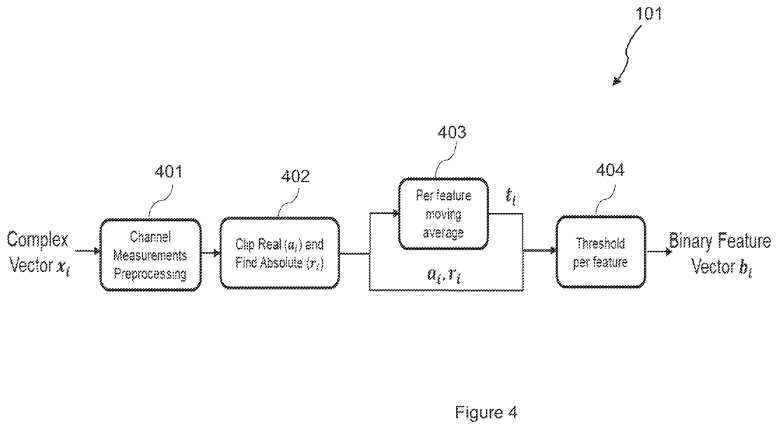

In one example, the online implementation of the binary compression module 101 is adopted, with CSI phase sanitization and CSI amplitude normalization in the pre-processing step. FIG. 4 shows this online implementation where the pre-processing and compression is performed in an online fashion. The input is a complex vector xᵢ. Each measurement is pre-processed at 401. At 402, the real (aᵢ) is clipped and the absolute (r e) is found. The compression step is performed with thresholding per feature, based on the mean value for each feature in the dataset X that is found with the help of a moving (or running) average per feature, as shown at 403. The result of the thresholding function is an output binary feature vector of similar length, i.e. 240 binary features. Therefore, each measurement is processed and used to update the trainable parameters of the binary compression module 101, which in this implementation is a vector t that keeps the moving average per feature of the input CSI and is then used as a threshold, as indicated at 404, to output a binary feature vector bᵢ.

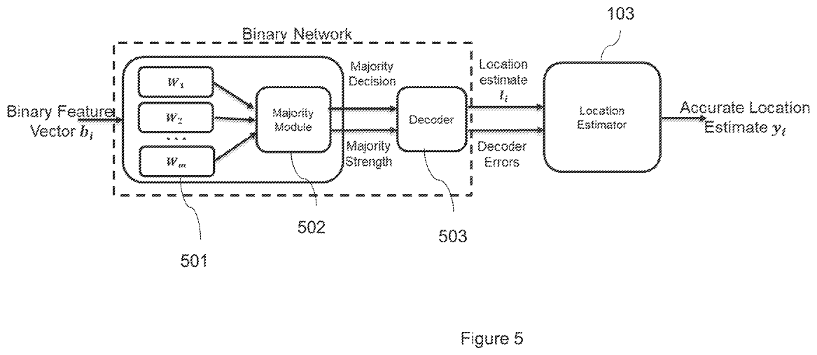

One exemplary implementation of the binary network module 102 is schematically illustrated in FIG. 5. A BNN classifier is used with the location area divided into a grid, where the binary network has neurons organized into m groups, as shown at 501. Each group may implement a different activation function or may have different connectivity to the input vector. A majority module 502 aggregates the decisions of groups and outputs both the decision of the majority and the majority strength, which indicates how confident this decision was. The decoder module 503 then acts as a weighted maximum likelihood decoder in order to provide the location estimate to the location estimator module 103, along with information about the confidence of this output, which may be represented by the number of estimated errors from the decoder.

The training of the binary network is based on an iterative algorithm that updates the weights by taking into account the current label estimates and the actual true labels.

The location estimator module 103 selects, based on the frequency of sampling, the location estimates produced by sequential measurements with sufficient separation in time (greater than the coherence time—the time duration where the channel can be considered not varying). This subsampling can be performed in order to avoid identical CSI values that can have a negative impact in the performance, due to exacerbating the weight of a single repeated output estimate (since the CSI values are identical) compared to statistically analyzing possible different outputs coming from slightly different measurements. Each location estimate can be seen as a vote for the center of each cell of the grid. The location estimator module 103 can specify the area of the grid with the maximum voting density. It may discard all the measurements that do not belong into this area.

To further improve the quality of the estimate, the location estimator module 103 may use a weighted average on the selected votes to calculate the final planar coordinates. The weight of each vote may be based on feedback from the binary network. In one embodiment, the decoding errors (Hamming distance of the majority output vector to the closest codeword) may be used, which is a metric of the confidence of the BNN for the specific estimation. By following this process, the final coordinates of the estimation are real coordinates on the plane. Therefore the solution may be more accurate and robust compared to simply providing an identifier of the estimated class, i.e. the estimated cell of the grid.

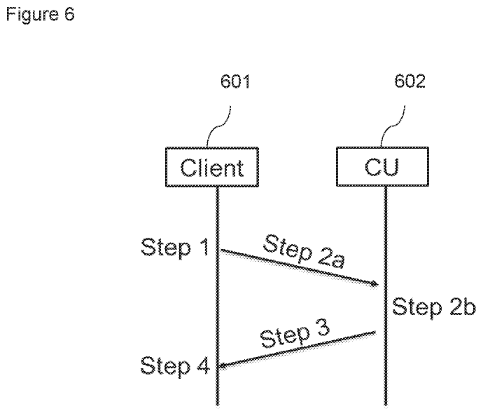

In an alternative embodiment, schematically illustrated in FIG. 6, the lightweight and low-overhead Binary Compression may enable multiple clients 601 to collect CSI measurements in various locations and then to transmit fast all the measurements to a Centralized Unit (CU) 602. Each client may be implemented by a separate device. The training of the BNN model can then take place at the CU 602, and the trainable parameters can be disseminated to the clients/devices 601 with low overhead. With reference to FIG. 6, the steps of the centralized training protocol are described in more detail below:
Step 1: The devices pre-process and compress complex CSI vectors to binary vectors by their Binary Compression module and then transmit them to a CU.
Step 2a: The CU collects the compressed binary CSIs.
Step 2b: The CU trains the binary neural network of its Binary Network module.
Step 3: The CU transmits the trainable parameters (neuron weights) of the BNN to the devices.
Step 4: The devices update their Binary Network models and they can now use CSI measurements to perform inference and provide location estimates on their own.

The multiple clients may be mobile devices and the CU may be a server. One or more processors of the mobile devices can be configured to compress each channel measurement. Each mobile device can be configured to transmit those compressed measurements to the server. One or more processors of the server can be configured to process the compressed forms of the channel measurements to train a neural network to form a plurality of intermediate location estimates and thereby form a set of neural network weights. The server can be configured to transmit the neural network weights to at least one of the mobile devices.

The lightweight binary compression therefore enables multiple devices to provide measurements quickly and with reduced communication overhead to the CU that performs the training, and then the binary trained model is easily disseminated to the devices.

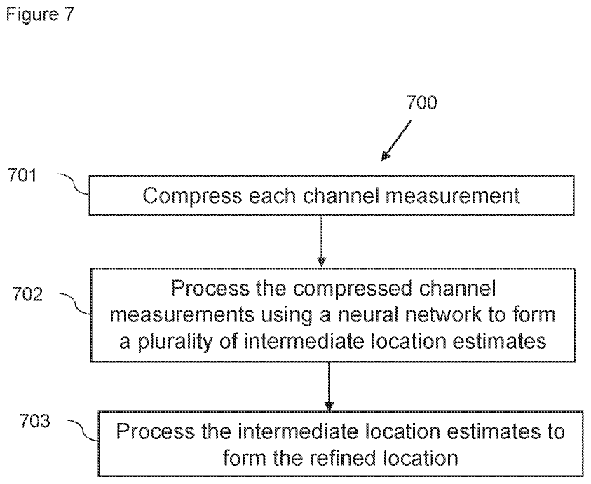

Summarised in FIG. 7 is an example of a computer-implemented method 700 for estimating a refined location in dependence on a plurality of measurements of one or more communication channels. At step 701, the method comprises compressing each channel measurement. At step 702, the method comprises processing the compressed channel measurements using a neural network to form a plurality of intermediate location estimates. At step 703, the method comprises processing the intermediate location estimates to form the refined location.

In a preferred example, the refined location is an estimate of the location of the apparatus. However, the location need not be that of the device comprising the processor that is performing the computations.

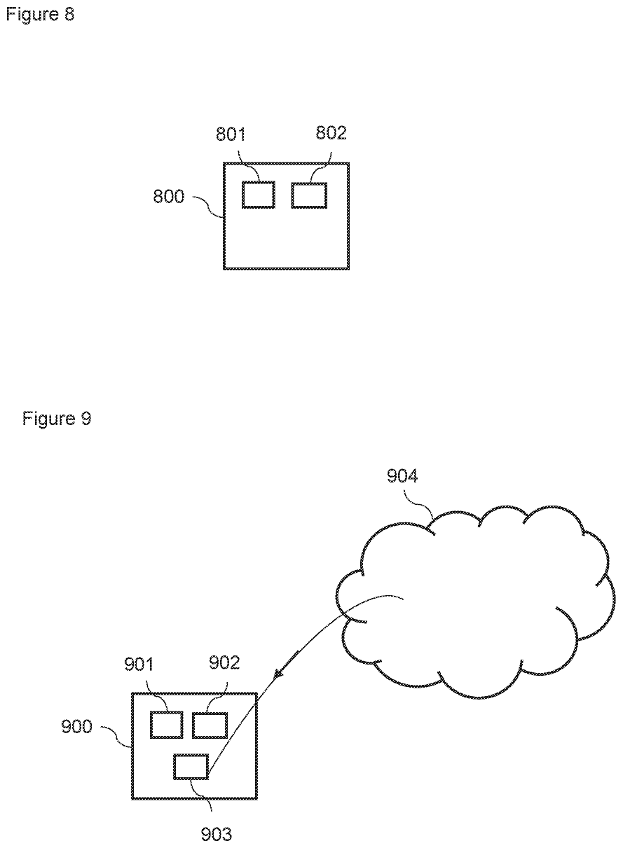

FIG. 8 is a schematic representation of an apparatus 800 configured to perform the method according to FIG. 7. The apparatus 800 may be implemented on a device, such as a laptop, tablet, smartphone, TV, robot, self-driving car, IoT, low-resource device for indoor localization, as well as on devices where energy saving is pursued.

The apparatus 800 comprises a processor 801 configured to form the refined location in the manner described herein. For example, the processor 801 may be implemented as a computer program running on a programmable device such as a Central Processing Unit (CPU). The apparatus 800 also comprises a memory 802 which is arranged to communicate with the processor 801. Memory 802 may be a non-volatile memory. The processor 801 may also comprise a cache (not shown in FIG. 8), which may be used to temporarily store data from memory 802. The apparatus may comprise more than one processor and more than one memory. The memory may store data that is executable by the processor. The processor may be configured to operate in accordance with a computer program stored in non-transitory form on a machine readable storage medium. The computer program may store instructions for causing the processor to perform its methods in the manner described herein. The apparatus may also comprise a transceiver for sending and/or receiving channel measurements.

As illustrated in FIG. 9, in one particular example, the apparatus is implemented on a mobile device 900 comprising a processor 901 (or more than one processor), a memory 902 and a transceiver 903 which can operate as a radio receiver. The processor 901 could also be used for the essential functions of the device. The mobile device may comprise a housing enclosing the radio receiver and the one or more processors. The transceiver 903 is configured to receive a set of channel measurements for radio frequency channels. In this example, the channel measurements are formed by the transceiver 903. The processor 901 can be configured to compress each channel measurement to a compressed form and transmit the compressed forms of the channel measurements to a server 904. The transceiver 903 is capable of communicating over a network with a server 904. The network may be a publicly accessible network such as the internet. In this example, the server 904 is a cloud server. However, other types of server may be used accordingly. The processor 901 can receive a set of neural network weights from the server and implement a neural network using the received weights to estimate a location of the mobile device 900.

The apparatus and method described herein may therefore allow for accurate and low-complexity on-device localization based on channel measurements. The localization system has a modular architecture. As described above, a Binary Compression module performs the pre-processing and compression steps, and prepares the input for the BNN fingerprinting. In the preferred implementation, the binary feature vector comprises invariant features for CSI fingerprinting. This may help to ensure accurate location prediction despite (location independent) noise in measurements and information quantization loss in compression. A Location Estimator module takes as input a set of BNN outputs (location estimates) along with feedback signals from the BNN that are specifically designed for CSI fingerprinting. This may, for example, determine the quality of each sample. The module may perform statistical analysis to provide the final strongly improved location estimate.

The network setup and protocol can be used for wireless (CSI) localization. Multiple devices with (WiFi, LTE, etc.) receiving equipment and binary localization equipment may be incorporated, while a single transmitter can provide the signal for the localization estimate.

In one case, the network can be set up for a centralized training protocol, where the lightweight binary compression enables multiple clients to provide measurements quickly and with reduced communication overhead to a Centralized Unit that performs the training, and then the binary trained model (BNN weights) is easily disseminated to the clients/devices.

For the performance evaluation of the previous embodiment, real experiments were performed in a WiFi network. The CSI measurements were received from a 1×4 Single Input Multiple Output (SIMO) channel with 30 subcarriers. The measurements were collected in two different campaigns for training and testing data respectively for a more realistic, yet challenging, problem, as CSI changes over time even if the measurements are taken at the exact same location. The location area of 1.5 m² was divided in a 10×10 grid.

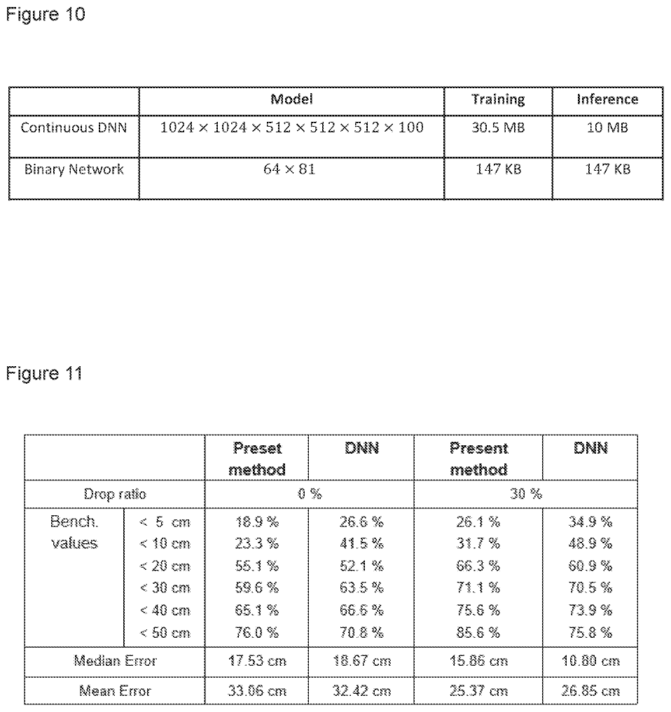

A comparison in terms of required memory for the neural network is presented in FIG. 10 between the low-complexity solution described herein and a standard approach with a DNN. In these examples, the dimensions of the DNN model were selected so that the percentage of prediction errors below 20 cm is maximized. The memory gains are of the order of ×200 times for the training phase, and x 70 times for the inference phase.

In addition to the gains from using a BNN instead of a DNN, the approach described herein may also provide additional significant gains from the Binary Compression module, particularly when the online approach is adopted. The required memory in this online case only for storing the complex dataset of CSI measurements is reduced by 32 times.

A comparison in terms of the achieved accuracy is presented in FIG. 11 between the approach described herein and a standard indoor localization approach with a DNN. The drop ratio indicates the percentage of the lower confidence solutions that the algorithm drops and does not proceed to their location estimation. The performance of the approach described herein is in some implementations comparable to the DNN that has much more available resources. In ˜70% of the measurements, the prediction is closer than 20 cm from the true location. This value is further increased to ˜80% when the same measurement campaign is used for both training and testing data.

The localization method described herein utilizes an approach with flexible and modular architecture that can store and process data and trainable parameters by exploiting the arithmetic representation of 1-bit (binary representation). This is extremely efficient in terms of computation and memory requirements and may provide high accuracy with good generalization properties when a suitable training algorithm is applied. In order to achieve this functionality, neural networks with binary trainable parameters are utilized that allow both training and inference phases to be executed on the device.

Embodiments of the present disclosure can enable indoor localization without dedicated hardware, since only channel measurements are needed. The approach enables having the receiver and localization processes on the device, due to the great reduction in the computation, memory and power requirements.

The approach allows for training and inference on a device, estimating position without compromising privacy. All calculations can be performed on the on-device receiver and can stay only on the device. Bandwidth can be saved on the network, as the receiver can be on the device and all localization processing can be performed on the device. Therefore, the bulky CSI measurements are not required to be transmitted, which would occupy a huge chunk of bandwidth.

The approach may save storage memory on a device, which is a problem observed in fingerprinting methods, since the CSI measurements that are used for training can comprise millions of complex numbers. More precisely, by using an online pre-processing approach, the required memory only for storing the complex dataset of CSI measurements can be reduced by 32 or 64, assuming single or double precision floating point representation for the original number.

The approach can provide a great trade-off of memory and power requirements and good localization accuracy, enabling deployment in all kinds of applications and devices. It is a binary solution which has very efficient hardware implementation and has a very flexible design. All of the component modules are parametrizable and can be fine-tuned according to the memory, power and localization parameters of the device. The approach exhibits strong generalization with low complexity and robust performance.

Each individual feature described herein and any combination of two or more such features are disclosed, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. Aspects of the present disclosure may consist of any such individual feature or combination of features. In view of the foregoing description it will be evident to a person skilled in the art that various modifications may be made within the scope of the invention.

What is claimed is:

1. An apparatus for estimating a refined location in dependence on a plurality of measurements of one or more communication channels, the apparatus comprising:
a memory configured to store instructions; and
one or more processors coupled to the memory and configured to execute the instructions to cause the apparatus to:
compress each channel measurement;
process the compressed channel measurements using a neural network to form a plurality of intermediate location estimates; and
process the intermediate location estimates to form the refined location.

2. The apparatus as claimed in claim 1, wherein each channel measurement is compressed to a binary form, the neural network is a binary neural network configured to operate in accordance with a neural network model defined by a set of weights, and all the weights are binary digits.

3. The apparatus as claimed in claim 2, wherein the one or more processors are configured to implement the neural network model using bitwise operations.

4. The apparatus as claimed in claim 1, wherein the one or more processors are configured to:
process the binary forms of the channel measurements using the neural network to form a respective measure of confidence for each intermediate location estimate; and
estimate the refined location in dependence on the measures of confidence.

5. The apparatus as claimed in claim 1, wherein each channel measurement is indicative of an estimate of channel state information for one or more radio frequency channels and on one or more antennas.

6. The apparatus as claimed in claim 1, wherein the one or more processors (801, 901) are configured to digitally pre-process each channel measurement.

7. The apparatus as claimed in claim 1, wherein the one or more processors are configured to delete each channel measurement once each channel measurement has been compressed.

8. The apparatus as claimed in claim 1, wherein each channel measurement is represented by a complex value comprising a real part and an imaginary part, and the one or more processors are configured to process each channel measurement by selecting a refined representation which comprises an amplitude of the complex value and the real part.

9. The apparatus as claimed in claim 8, wherein the one or more processors are configured to compress the refined representation of the channel state information estimates for each channel measurement into a compressed representation.

10. The apparatus as claimed in claim 1, wherein the refined location is an estimate of a location of the apparatus.

11. The apparatus as claimed in claim 1, wherein the neural network is configured to operate as a multi-class classifier, wherein a class estimate corresponds to a location on a discretized space.

12. A mobile device comprising:
a memory configured to store instructions; and
one or more processors coupled to the memory and configured to execute the instructions to cause the mobile device to:
receive a set of channel measurements for radio frequency channels;
compress each channel measurement to a compressed form;
transmit the compressed forms of the channel measurements to a server;
receive from the server a set of neural network weights; and
implement a neural network using the received weights to estimate a location of the mobile device.

13. The mobile device as claimed in claim 12, further comprising a radio receiver, wherein the channel measurements are formed by the radio receiver.

14. A method for estimating a refined location in dependence on a plurality of measurements of one or more communication channels, the method implemented by a processor of an apparatus comprising:
compressing each channel measurement;
processing the compressed channel measurements using a neural network to form a plurality of intermediate location estimates; and
processing the intermediate location estimates to form the refined location.

15. The method as claimed in claim 14, wherein each channel measurement is compressed to a binary form, the neural network is a binary neural network configured to operate in accordance with a neural network model defined by a set of weights, and all the weights are binary digits.

16. The method as claimed in claim 15, wherein the one or more processors are configured to implement the neural network model using bitwise operations.

17. The method as claimed in claim 14, wherein the one or more processors are configured to:
process the binary forms of the channel measurements using the neural network to form a respective measure of confidence for each intermediate location estimate; and
estimate the refined location in dependence on the measures of confidence.

18. The method as claimed in claim 14, wherein each channel measurement is indicative of an estimate of channel state information for one or more radio frequency channels and on one or more antennas.

19. The method as claimed in claim 14, wherein the one or more processors (801, 901) are configured to digitally pre-process each channel measurement.

20. The method as claimed in claim 14, wherein the one or more processors are configured to delete each channel measurement once each channel measurement has been compressed.
